(19) United States
(12) Patent Application Publication
(10) Pub. No.: US 2006/0022264 A1
(43) Pub. Date: Feb. 2, 2006

(54) Method of making a double gate semiconductor device with self-aligned gates and structure thereof

(76) Inventors: Leo Mathew, Austin, TX (US); Yang Du, Austin, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 10/909,095

(22) Filed: Jul. 30, 2004

(51) Int. Cl. H01L 29/78; H01L 21/336

(52) U.S. Cl. 257/331; 438/283; 438/279; 257/366

(57) ABSTRACT

A double gated device is made by forming a first gate on top of a first substrate and over a channel. Etching into the substrate, using the gate as a mask, forms recesses that are filled with a material that etches selectively to the material of the substrate that is adjacent to the recesses and under the channel. A second substrate is attached over the first gate so that the major portion of the first substrate can be removed. The portion of the remaining substrate between the source/drain regions is removed to form a gate recess for a second gate. The channel is preferably of a different material from that being etched so that it will act as an etch stop during this step. A sidewall spacer is formed along the sidewall of the gate recess and a second gate is formed in the gate recess to obtain self-aligned gates.

### BACKGROUND

The present disclosures relate generally to semiconductor devices, and more particularly, to a double gate semiconductor device and method of making a double gate device with self-aligned gates.

With respect to known double gate device structures, the same suffer from misalignment and/or overlap of a front gate with a back gate. In addition, known techniques generally require major layout changes. Still further, channel thicknesses of the double gate device structures are not very well controlled. In addition, the known double gate devices suffer from one or more problems of not having self aligned gates and needing a complex epitaxial process for source drain contacts.

Accordingly, it would be desirable to provide an improved transistor structure and method of making the same for overcoming the problems in the art.

### SUMMARY

According to one embodiment, a method of making a semiconductor device includes forming a first gate separated from a first substrate by a first gate dielectric. The first substrate comprises a channel of semiconductor material adjacent to the gate dielectric, a sacrificial region adjacent to the channel, and a mechanical support region adjacent the sacrificial region. The first substrate is etched using the first gate as a mask to form recesses in the first substrate. Source/drain regions are formed in the recesses. A second substrate is provided adjacent the gate for use as a mechanical support for the semiconductor device. Substantially, the mechanical support region of the first substrate and the sacrificial region are removed to provide a gate recess having a sidewall. The method further includes forming a second gate in the gate recess and adjacent to the channel.

### BRIEF DESCRIPTION OF THE DRAWINGS

The embodiments of the present disclosure are illustrated by way of example and not limited by the accompanying figures, in which like references indicate similar elements, and in which:

FIGS. 1-7 are cross-sectional views of various steps in the method of making a planar double gate semiconductor device with self-aligned spacers and gates according to one embodiment of the present disclosure;

FIG. 8 is a cross-sectional view of an alternate step in the method of making a planar double gate semiconductor device with self-aligned spacers and gates according to another embodiment of the present disclosure;

FIG. 9 is a cross-sectional view of another step in the method of making a planar double gate semiconductor device with self-aligned spacers and gates according to one embodiment of the present disclosure;

FIG. 10 is a top plan view of a planar double gate semiconductor device with self-aligned spacers and gates according to one embodiment of the present disclosure;

FIG. 11 is a cross-sectional view of the double gate semiconductor device of FIG. 10 according to one embodiment of the present disclosure;

FIG. 12 is a top plan view of a planar double gate semiconductor device with self-aligned spacers and gates according to another embodiment of the present disclosure;

FIG. 13 is a cross-sectional view of the double gate semiconductor device of FIG. 12 according to one embodiment of the present disclosure;

FIG. 14 is a top plan view of a planar double gate semiconductor device with self-aligned spacers and gates according to another embodiment of the present disclosure;

FIG. 15 is a cross-sectional view of the double gate semiconductor device of FIG. 14 according to one embodiment of the present disclosure;

FIG. 16 is a cross-sectional view of an alternate method of making a planar double gate semiconductor device with self-aligned spacers and gates according to another embodiment of the present disclosure; and

FIG. 17 is a cross-sectional view of a double gate semiconductor device according to another embodiment of the present disclosure.

The use of the same reference symbols in different drawings indicates similar or identical items. Skilled artisans will also appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION

FIGS. 1-7 are cross-sectional views of various steps in the method of making a planar double gate semiconductor device 10 with self-aligned spacers and gates according to one embodiment of the present disclosure. Referring now to FIG. 1, formation of the planar double gate semiconductor device 10 begins with providing a substrate 12. Substrate 12 comprises a bulk substrate, such as silicon, germanium, or any other suitable substrate. A sacrificial formation layer 14 is formed overlying the substrate 12. Sacrificial formation layer 14 comprises any suitable material having an etch selectivity to a material of a subsequently formed channel region.

In another embodiment, the sacrificial formation layer 14 comprises one or more layers of material and/or one or more layers that together have one or more etch selectively boundaries. An etch selective boundary could include any boundary suitable for an end point detection. For example, germanium, boron, arsenic implants or silicon germanium epitaxial layers, or other suitable material can be used to define the sacrificial formation layer.

Subsequent to formation of the sacrificial formation layer 14 on substrate 12, a channel layer 16 is formed. The channel layer 16 comprises any suitable material for a given semiconductor device application. For example, the channel layer 16 can comprise one of silicon, silicon-germanium, strained silicon, or other suitable material. Furthermore, channel layer 16 can include one or more of: an epitaxial layer or layers, a deposited and re-crystallized layer or layers, and a combination of the same. Accordingly, this process allows for a very well controlled channel thickness to be obtained, for example, within as few as one or more atomic layers.

A portion of the layers 14 and 16 are then patterned and etched for the formation of shallow trench isolation regions (STI) 18. Shallow trench isolation regions 18 are formed, for example, using well known techniques such as dielectric deposition and chemical-mechanical polishing (CMP). In some embodiments, the STI is optional.

Following the formation of shallow trench isolation regions 18, a gate dielectric 20 is formed overlying the channel layer 16. Gate dielectric 20 can include, for example, silicon oxide, silicon nitride, hafnium oxide, hafnium oxy-nitride, or any combination of the same. Alternatively, gate dielectric 20 comprises any dielectric that is suitable for the requirements of a particular semiconductor device application.

Subsequent to formation of the first gate dielectric 20, a first gate electrode 22 and an optional hard mask 23 are formed overlying gate dielectric 20, using well known techniques such as deposition, pattern, and etch using materials suitable for the requirements of a particular semiconductor device application. The optional hard mask 23 can include, for example, a nitride, an oxide or a metal layer(s). For example, gate electrode 22 can comprise one or more of silicon, silicon-germanium, silicides and metals (such as TiN, TaSiN, Mb, Co, Ni, or combinations thereof and the like). Such gate electrode materials can furthermore be doped using in-situ doping and/or implantation processes, as may be needed for the requirements of a particular semiconductor device application.

The method further includes forming source/drain extension regions 24 within the material of channel layer 16, using the gate electrode 22 as a mask. Accordingly, portions of the channel layer 16 that do not directly underlie the gate electrode 22 are doped to form the source/drain extension regions 24.

Following formation of the source/drain extension regions 24, sidewall spacers 26 are formed. Sidewall spacers 26 comprise any suitable sidewall spacer for the requirements of a particular semiconductor device application. For example, sidewall spacers 26 are formed by deposition and anisotropic etch of a dielectric layer or layers such as silicon dioxide, silicon nitride, or other suitable dielectric.

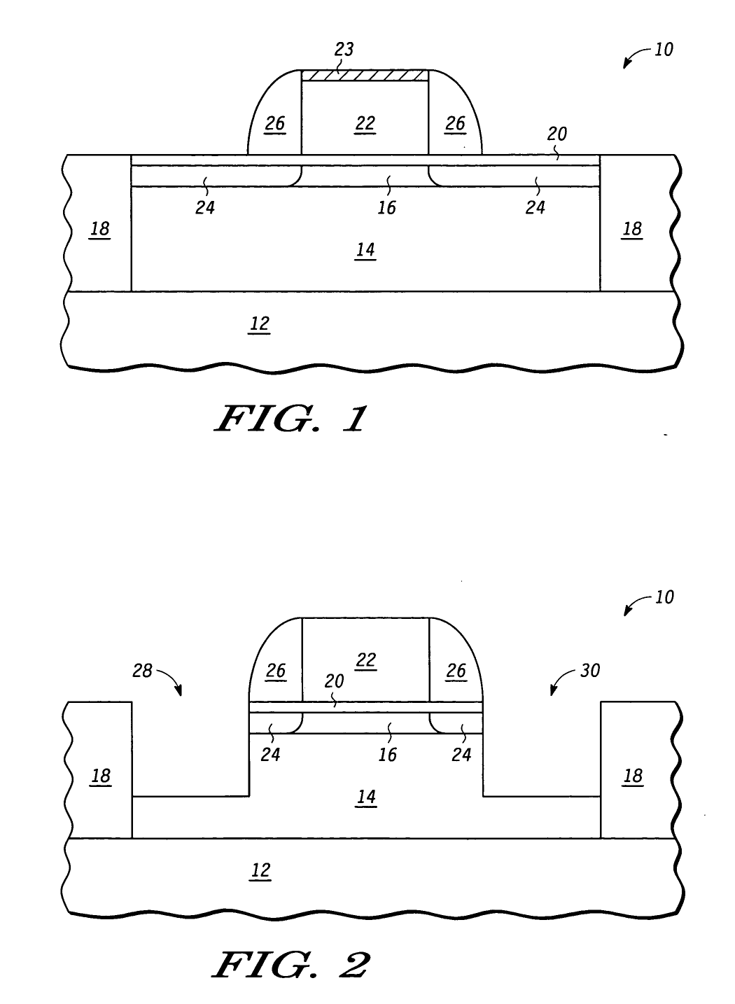

Referring now to FIG. 2, recesses 28 and 30 are formed by removing portions of the gate dielectric 20, portions of the source/drain extension regions 24 of channel layer 16, and portions of the sacrificial formation layer 14, furthermore, using the gate electrode 22 and sidewall spacers 26 as a mask. The removal process can include, for example, by an anisotropic etch of portions of the respective layers 20, 24, and 14. If an optional hard mask 23 has been used, then the same can be removed subsequent to the formation of the recesses 28 and 30.

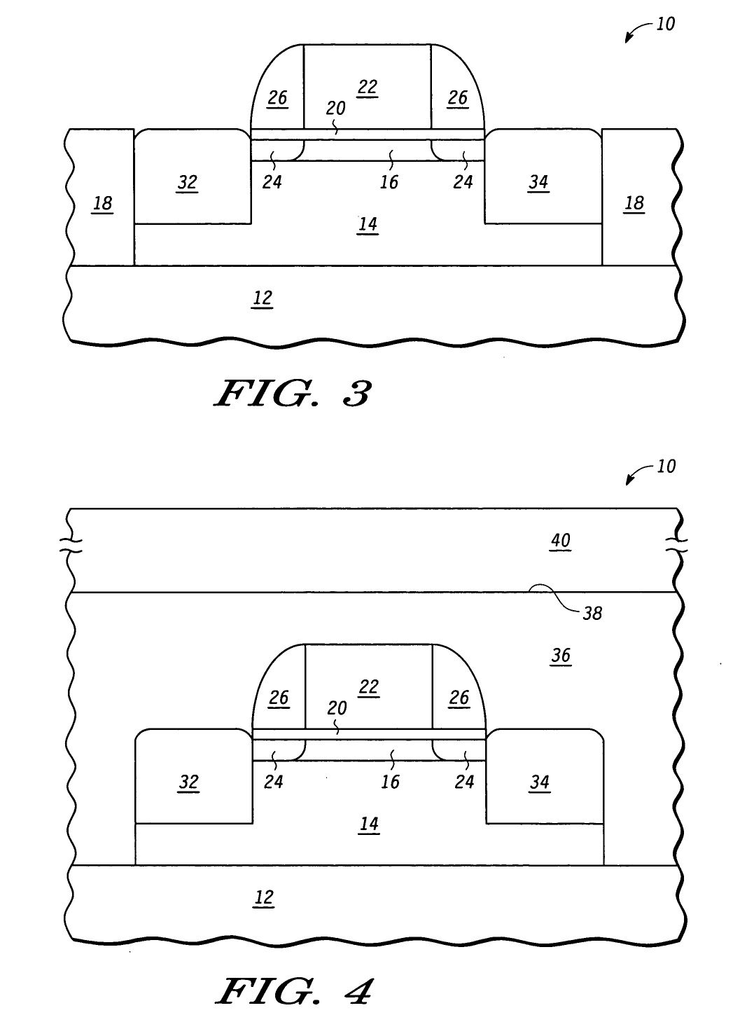

In FIG. 3, a semiconductor material (or semiconductor materials), such as silicon, silicon-germanium, or the like, is grown within recesses 28 and 30 using standard techniques, such as epitaxial growth. The semiconductor material indicated by reference numerals 32 and 34 subsequently become one of a source or drain region of the dual gate semiconductor device 10. It should be appreciated that inside edges of the newly formed source/drain regions are formed in alignment with corresponding outside edges of sidewall spacers 26. In addition, if the optional hard mask 23 has been removed and the first gate electrode material is silicon, then there could also be some epitaxial growth overlying the first gate electrode 22.

In FIG. 4, a dry etch can be used for optionally removing STI regions 18 that are exposed, outside a region underlying gate electrode 22. There will still exist some portions of STI 18 (not shown) that underlie gate electrode 22 and that are orthogonal to the structure shown in FIG. 4. Thereafter, a dielectric layer 36 is formed or deposited overlying a top surface of the structure of FIG. 3, the dielectric layer 36 having a planarized surface 38. Dielectric layer 36 can include, for example, any suitable dielectric material that is or has been planarized. Planarization can be accomplished via one or more of chemical mechanical polishing, etch back techniques, or spin-on dielectric material processing. Subsequent to formation of the planarized dielectric layer 36, a transfer substrate 40 is attached to dielectric layer 36. Substrate 40 can be attached to dielectric layer 36 via thermal bonding, processing or other suitable bonding techniques. Transfer substrate 40 comprises any suitable rigid substrate, for example, a semiconductor substrate, a glass substrate, a quartz substrate, or the like.

Following attachment of transfer substrate 40 to dielectric layer 36, the starting substrate 12 is then removed. Various removal techniques can be employed, such as, one or more of chemical-mechanical polishing of the substrate 12, hydrogen implant and anneal processing, selective etch of silicon-germanium layers using hydrogen peroxide wet etch, or liquid high pressure wet etch processing. Upon removal of the substrate 12, various regions on an opposite side of the channel layer 16 from the first gate electrode are now exposed for processing according to the embodiments of the present disclosure.

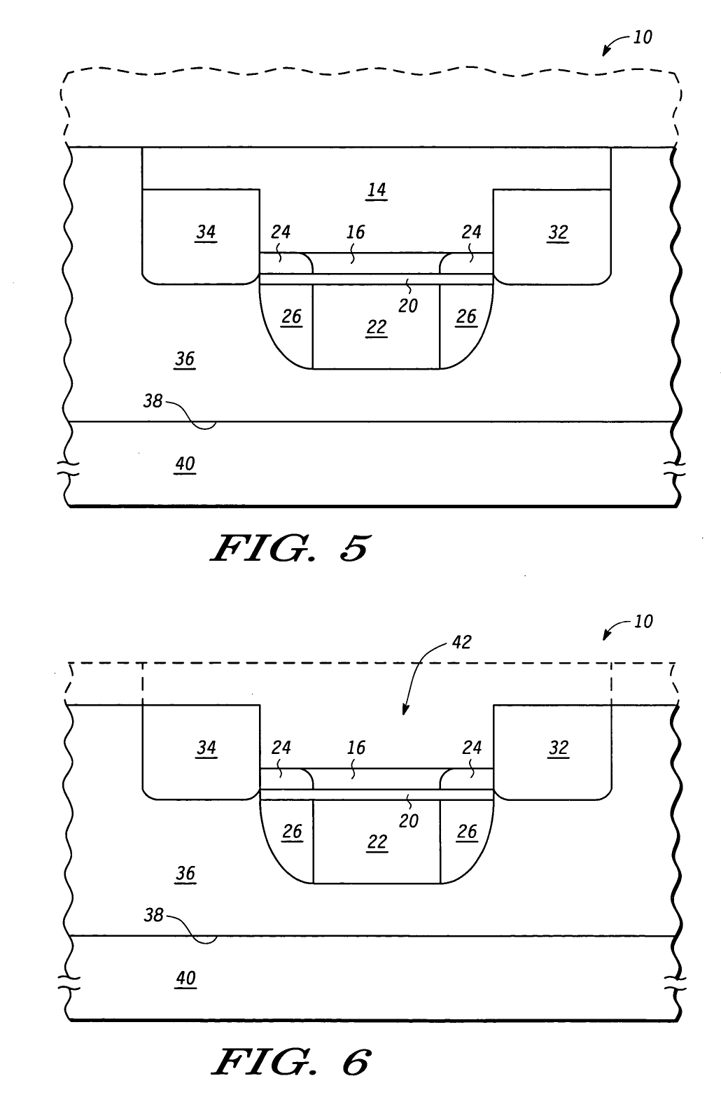

For illustration purposes, the illustration in FIG. 5 is similar to the structure of FIG. 4 subsequent to removal of substrate 12, only now inverted. That is, the regions on the opposite side of the channel layer 16 from the first gate electrode are now at the top of the figure in FIG. 5.

Turning now to FIG. 6, the structure is subjected to one or more of a dry etch, wet etch, or combination thereof, for removing the sacrificial formation layer 14 and a portion of the shallow trench isolation regions 18 (not shown) orthogonal to the Figure that were not previously removed. As shown, a portion of dielectric layer 36 is also removed, for example, as shown. An example of dry etch includes a plasma etch with CF₄ for removal of silicon germanium. An example of a wet etch includes hydrogen peroxide etch for removal of silicon germanium. In one embodiment, all material of the sacrificial formation layer 14 is removed. In another embodiment, portions of the sacrificial formation layer 14 and shallow trench isolation 18 are removed, further as discussed herein.

Removal of the sacrificial formation layer 14 forms an opening indicated by reference numeral 42, the opening having substantially vertical sidewalls 43. Note that region 14 has an etch selectivity to that of regions 34, 32, and 16, and hence can be selectively removed. Furthermore, it is noted that removal of the sacrificial formation layer 14 results in the creation of substantially straight sidewalls 43. In addition, the sidewalls 43 are aligned with respective ones of an underlying outside edge of the sidewall spacers 26. It should be noted that opening 42 extends in an orthogonal direction to that as shown, wherein this facilitates formation of a second gate. Formation of the second gate in the orthogonal direction of the opening 42 is discussed further herein with respect to FIGS. 11-15.

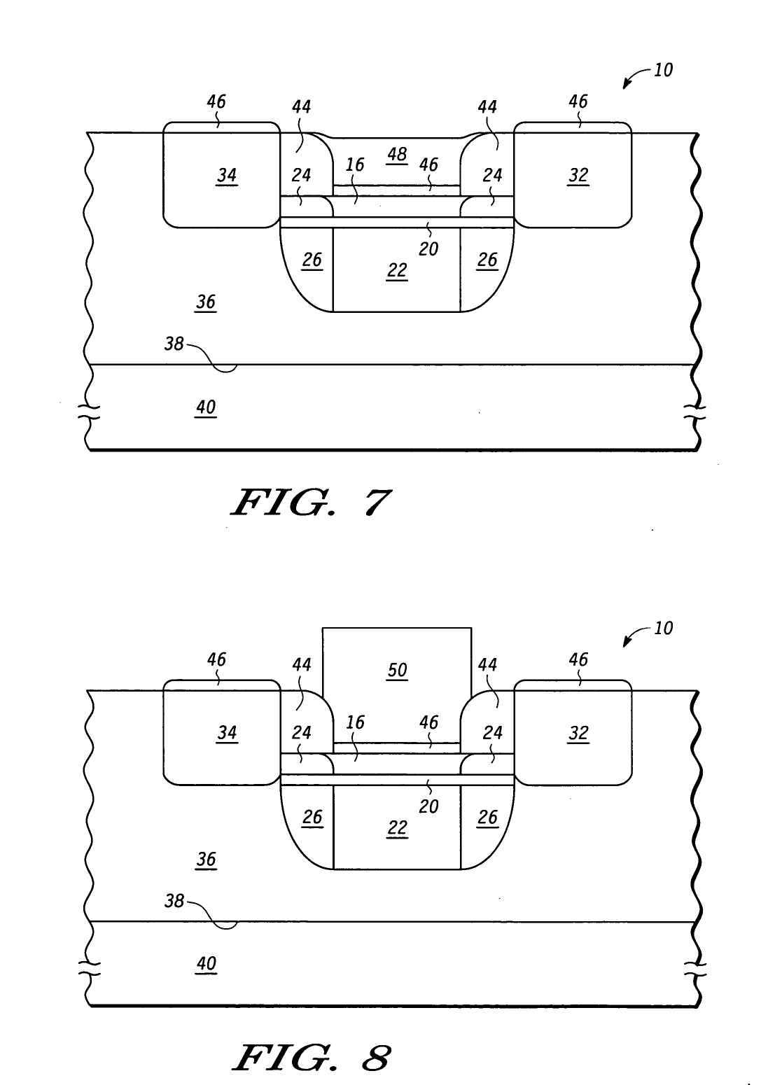

Referring now to FIG. 7, the process of making the dual gate electrode semiconductor device 10 continues with formation of sidewall spacers 44 within opening 42. Sidewall spacers 44 can be formed to be substantially self-aligned with sidewall spacers 26. A second gate dielectric 46 is then formed overlying an exposed portion of channel layer 16 within opening 42. Second gate dielectric 46 can comprise a same material as the first gate dielectric 20 or a material different from that of first gate dielectric 20. Formation of second gate dielectric 46 is similar to that as described for formation of the first gate dielectric 20.

Following the formation of second gate dielectric 46, a second gate electrode 48 is formed. Second gate electrode 48 comprises a self-aligned gate electrode that is self-aligned to the underlying first gate electrode 22. Formation of the second gate electrode 48 can be accomplished, for example, using deposition and etch back techniques. Second gate electrode 48 comprises a material selected according to the requirements of a particular semiconductor device application. For example, second gate electrode 48 can comprise a material similar to that of first gate electrode 22 or a different material from that of the first gate electrode 22. Furthermore, the material of second gate electrode 48 can be doped and diffused with a different doping species and/or dose than that of first gate electrode 22. Alternatively, the second gate electrode can also be formed by deposition, patterning, and etching, such as shown in FIG. 8 and indicated by reference numeral 50.

Referring now to FIG. 9, following the formation of the second gate electrode 48, regions 32 and 34 are doped via ion implantation with ions 52 to form electrically active source/drain regions. A depth of the ion implantation and subsequent diffusion is generally represented by the dashed lines 54 in FIG. 9. It should be noted that a portion of (or substantially all of) the regions of 32 and 34 can be doped. Furthermore, it should be noted that the dopant diffusion can also extend into a portion of the channel layer 16 and/or the source/drain extension regions 24. Silicide regions 56 are then formed in desired areas using well known clean and silicide processes. For example, cobalt or nickel are deposited subsequent to an HF clean. In addition, annealed and unsilicided metal is then removed.

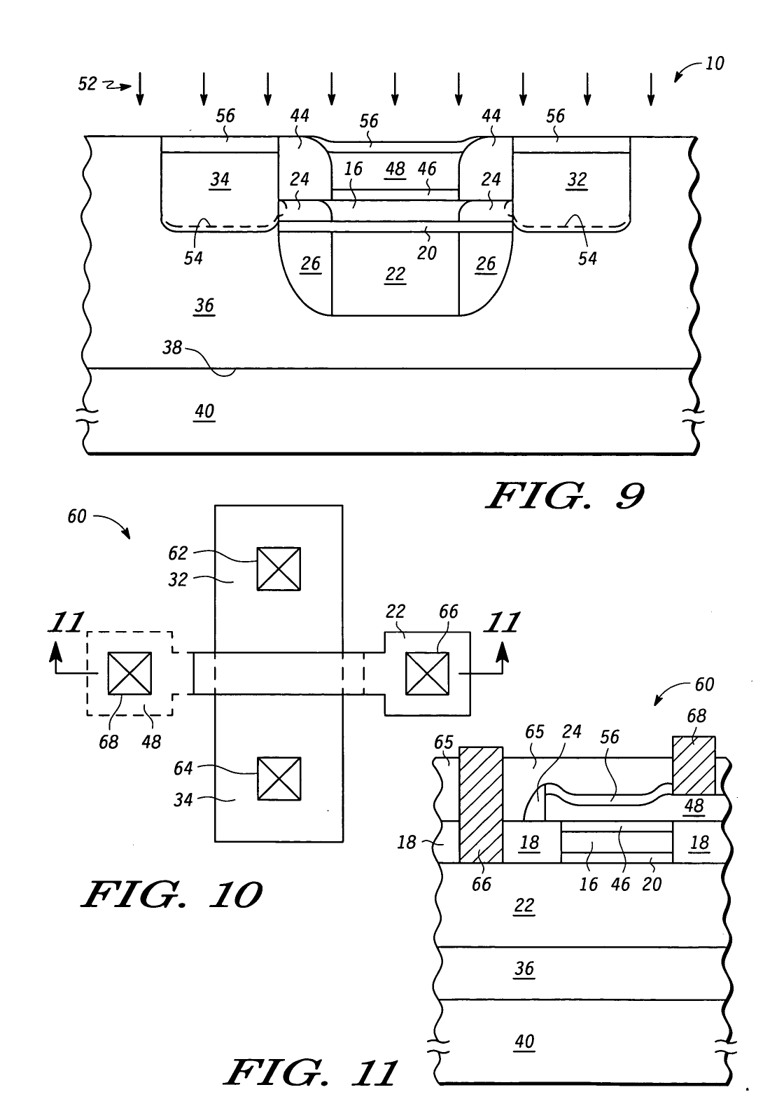

FIG. 10 is a top plan view of a double gate semiconductor device 60 with self-aligned gates according to one embodiment of the present disclosure. In the top plan view, the source/drain regions 32 and 34 are contacted via respective contacts 62 and 64. Furthermore, second gate electrode 48 is illustrated as overlying the first gate electrode 22, with intermediate layers as previously discussed herein, such as the orthogonal STI layers 18 that remain. In this embodiment, the first gate electrode 22 and the second gate electrode 48 are separately contacted via respective contacts 66 and 68. Accordingly, in this embodiment, the first gate electrode 22 is electrically isolated, that is, not electrically coupled to the second gate electrode 48.

FIG. 11 is a cross-sectional view of the double gate semiconductor device of FIG. 10, taken along line 11-11, according to one embodiment of the present disclosure. As shown, contact 66 is electrically coupled to the first gate electrode 22 and extends from first gate electrode 22 to the top surface of structure 60. Contact 68 is electrically coupled to the second gate electrode 48 via silicide region 56 and extends from second gate electrode 48 to the top surface of structure 60.

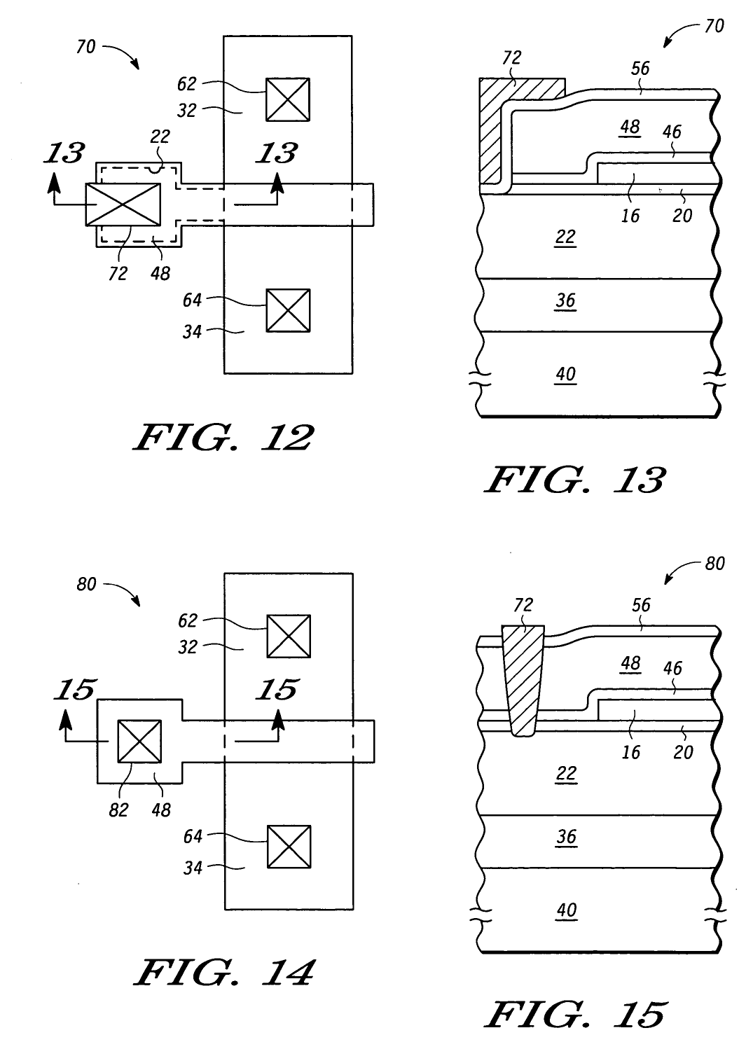

FIG. 12 is a top plan view of a double gate semiconductor device 70 with self-aligned gates according to another embodiment of the present disclosure. In the top plan view, the source/drain regions 32 and 34 are contacted via respective contacts 62 and 64. Furthermore, second gate electrode 48 is illustrated as overlying the first gate electrode 22, with intermediate layers as previously discussed herein. In this embodiment, the second gate electrode 48 is patterned to be slightly smaller than a similar pattern of the first gate electrode 22, to enable electrical coupling via a silicide region or an enlarged contact, as discussed further herein with respect to FIG. 13. Furthermore, contact 72 provides electrical contact to the second gate electrode 48, as well as to first gate electrode 22.

FIG. 13 is a cross-sectional view of the double gate semiconductor device of FIG. 12, taken along line 13-13, according to one embodiment of the present disclosure. Contact 72 is electrically coupled to the second gate electrode 48 via silicide region 56 and extends from second gate electrode 48 to the top surface of structure 70. Contact 72 also extends and electrically couples to the first gate electrode 22, for example, via silicide region 56. In such an instance, the silicide region 56 extends along a portion of second gate electrode 48. The first gate electrode 22 can be further electrically coupled to the second gate electrode 48 via the contact 72.

FIG. 14 is a top plan view of a double gate semiconductor device 80 with self-aligned gates according to another embodiment of the present disclosure. In the top plan view, the source/drain regions 32 and 34 are contacted via respective contacts 62 and 64. Furthermore, second gate electrode 48 is illustrated as overlying the first gate electrode 22, with intermediate layers as previously discussed herein. In this embodiment, the second gate electrode 48 is etched to form a through-hole that extends into the first gate electrode 22, to enable electrical coupling between the first and second gate electrodes via conductive plug or contact 82, as discussed further herein with respect to FIG. 15. Furthermore, conductive plug 82 provides electrical contact to the second gate electrode 48, as well as to first gate electrode 22.

FIG. 15 is a cross-sectional view of the double gate semiconductor device of FIG. 14, taken along line 15-15, according to one embodiment of the present disclosure. As shown, conductive plug 82 is electrically coupled to the second gate electrode 48 and to the first gate electrode 22.

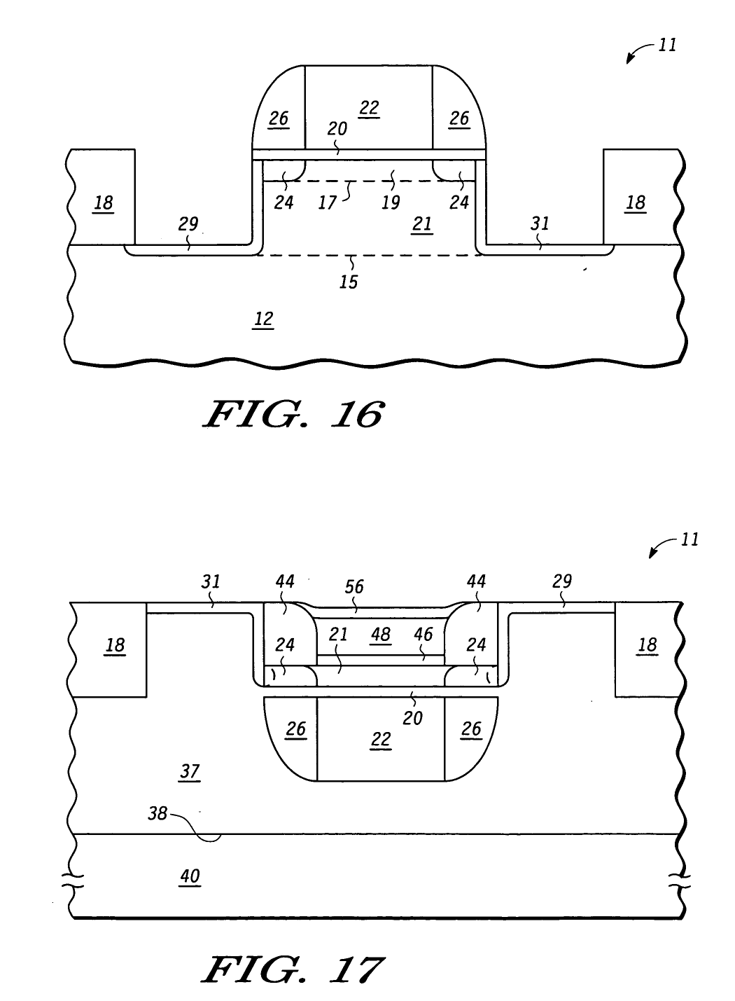

FIG. 16 is a cross-sectional view of an alternate method of making a planar double gate semiconductor device 11 with self-aligned gates according to another embodiment of the present disclosure. The semiconductor device 11 of FIG. 16 is similar to that discussed herein above with respect to the prior figures, with the following differences. The initial starting substrate 12 is selected to include first and second etch boundaries, 15 and 17, respectively. Etch boundaries 15 and 17 can comprise, for example, thin implanted or epitaxially grown layers, such as, germanium, boron, or the like. The etch boundaries act as an etch trace for dry etching of the substrate 12 at desired locations. The region between the first and second etch boundaries 15 and 17 is indicated by reference numeral 19. Similarly, the region between the second etch boundary 17 and the gate dielectric 20 is indicated by reference numeral 21. In addition, subsequent to formation of the recesses 28 and 30 of FIG. 2, the embodiment of FIG. 16 is subjected to a silicidation process for forming silicided regions 29 and 31. Silicided regions 29 and 31 provide an etch selectivity to regions 19 and 21. Etch selectivity is needed during subsequent processing, similarly as previously discussed herein with respect to FIGS. 5-9.

FIG. 17 is a cross-sectional view of the double gate semiconductor device 11 formed from the starting substrate of FIG. 16, according to an alternate embodiment of the present disclosure. Similarly, as discussed herein above with respect to FIG. 9, a depth of the ion implantation and subsequent diffusion is generally represented by the dashed lines 55 in FIG. 17. It should be noted that the dopant diffusion can also extend into a portion of the channel layer 21 and/or the source/drain extension regions 24.

As discussed herein, according to one embodiment, a method of making a semiconductor device includes forming a first gate separated from a first substrate by a first gate dielectric. The first substrate comprises a channel of semiconductor material adjacent to the gate dielectric, a sacrificial region adjacent to the channel, and a mechanical support region adjacent the sacrificial region. The first substrate comprises, for example, silicon. The channel comprises, for example, silicon. The sacrificial layer comprises, for example, silicon germanium.

The first substrate is etched using the first gate as a mask to form recesses in the first substrate and source/drain regions are formed in the recesses. Forming the source/drain regions can comprise, for example, epitaxially growing silicon. In another embodiment, forming the source/drain regions comprises forming layers of silicide in the recesses. A second substrate is provided adjacent the gate for use as a mechanical support for the semiconductor device. Substantially, the mechanical support region of the first substrate and the sacrificial region are removed to provide a gate recess having a sidewall. The method further includes forming a second gate in the gate recess and adjacent to the channel.

The method further includes forming a first sidewall spacer around the first gate and forming a second sidewall spacer on the sidewall of the gate recess prior to forming the second gate. The first sidewall spacer and the second sidewall spacer can comprise, for example, nitride. The channel, the sacrificial region, and the mechanical support region can comprise, for example, continuous monocrystalline silicon.

In another embodiment, the method includes forming a second gate dielectric on the channel region after removing the sacrificial region and before forming the second gate. In addition, the first gate dielectric has a dielectric constant different from that of the second gate dielectric. In yet another embodiment, the first gate comprises a different material than the second gate to form asymmetric gate device.

According to another embodiment of the present disclosure, a method of making a semiconductor device includes forming a first gate with a first sidewall spacer separated from a first substrate by a first gate dielectric. The first substrate comprises a channel of semiconductor material adjacent to the gate dielectric, a sacrificial region adjacent to the channel, and a mechanical support region adjacent the sacrificial region. The method further includes etching into the first substrate using the first gate and the first sidewall spacer as a mask to form recesses in the first substrate. Subsequent to forming the recesses, source/drain regions are formed in the recesses.

A second substrate is then provided adjacent the gate for use as a mechanical support for the semiconductor device. The method proceeds with substantially removing the mechanical support region of the first substrate and removing the sacrificial region to provide a gate recess having a sidewall. A second sidewall spacer is formed on the sidewall, followed by forming a second gate in the gate recess and adjacent to the channel.

According to another embodiment, a semiconductor device comprises a channel region; a first gate dielectric on a first side of the channel region; a second gate dielectric on a second side of the channel region; a first gate on the first gate dielectric; and a second gate on the second gate dielectric, wherein the second gate is narrower where it is on the second gate dielectric than where it is spaced from the second gate dielectric. The semiconductor device further comprises a first sidewall spacer around the first gate; and a second sidewall spacer around the second gate. In one embodiment, the first sidewall spacer has an inner edge that is substantially vertical and outer edge that slopes toward the first gate and the second sidewall spacer has an inner edge that slopes away from the second gate and an outer edge that is substantially vertical.

According to yet another embodiment, a semiconductor device comprises: a channel region; a first gate dielectric on a first side of the channel region; a second gate dielectric on a second side of the channel region; a first gate on the first gate dielectric; and a second gate on the second gate dielectric; a first sidewall spacer around the first gate; and a second sidewall spacer around the second gate. In addition, the first sidewall spacer has an inner edge that is substantially vertical and outer edge that slopes toward the first gate and the second sidewall spacer has an inner edge that slopes away from the second gate and an outer edge that is substantially vertical.

The method and apparatus of the present embodiments provide for two gates on both sides of a channel, wherein the gates are self aligned over the channel. The channel thickness is controlled by deposition, and thus can be very thin. In addition, the two gate electrodes and gate materials can be of different thickness, materials and conductivity. In one embodiment, a silicide (or differential etching material) extends deep into the silicon and forms a sidewall to allow dielectric spacers on its sides. End point and/or separation layers, such as Ge, are used to allow accurate etch end point and wafer peeling. Furthermore, a sacrificial partial gate pattern allows for a second gate to be self aligned to the first gate. The embodiments also provide for a planar transistor structure and method that allows self aligned gates on both sides of controlled channels.

Furthermore, the embodiments of the present disclosure overcome problems or limitations as discussed herein above, by one or more of the following. The embodiments allow for producing a double gate device with self aligned front and back gates. No major layout changes are required to implement a double gate device. Channel thickness can be very well controlled. Various options such as asymmetric gates, asymmetric spacers, and dielectric can be implemented. The embodiments also provide a simple solution for a gate all-around architecture. Still further, some versions allow for bulk starting wafers to be reused and end up with insulator surrounded silicon (ISS) devices.

Advantages provided by the embodiments of the present disclosure, can include, but are not limited to the following. Control of channel thickness allows very good control of transistor characteristics such as short channel effect (SCE0. The method allows a process which can reuse the starting wafer. The method further allows for more options such as partially-depleted SOI (PDSOI), fully-depleted SOI (FDSOI), bulk, asymmetric gates, independent gates, or any combination thereof, to be integrated. The method can further provide for devices having reduced junction capacitances, improved radiation hardness, and noise immunity since the channel can be surrounded by insulator. In addition, devices formed using bulk wafers generally cost less than devices formed using SOI for similar devices. Still further, the embodiments of the present disclosure advantageously provide a method for aligning a front and back gate of a double-gate device. Moreover, the embodiments enable a process such as silicide/SiGe growth on the S/D region on a front side of a double gated transistor structure to self align with a gate for the back side.

In the foregoing specification, the disclosure has been described with reference to various embodiments. However, one of ordinary skill in the art appreciates that various modifications and changes can be made without departing from the scope of the present embodiments as set forth in the claims below. Accordingly, the specification and figures are to be regarded in an illustrative rather than a restrictive sense, and all such modifications are intended to be included within the scope of the present embodiments.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the term “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. A method of making a semiconductor device, comprising:
forming a first gate separated from a first substrate by a first gate dielectric, the first substrate comprising a channel of semiconductor material adjacent to the gate dielectric, a sacrificial region adjacent to the channel, and a mechanical support region adjacent the sacrificial region;
etching into the first substrate using the first gate as a mask to form recesses in the first substrate;
forming source/drain regions in the recesses;
providing a second substrate adjacent the gate for use as a mechanical support for the semiconductor device;
substantially removing the mechanical support region of the first substrate;
removing the sacrificial region to provide a gate recess having a sidewall; and
forming a second gate in the gate recess and adjacent to the channel.

2. The method of claim 1, wherein the channel comprises silicon.

3. The method of claim 1, wherein the sacrificial layer comprises silicon germanium.

4. The method of claim 1, wherein the first substrate comprises silicon.

5. The method of claim 1, wherein the forming the source/drain regions comprises epitaxially growing silicon.

6. The method of claim 1, wherein the forming the source/drain regions comprises forming layers of silicide in the recesses.

7. The method of claim 1, further comprising:
forming a first sidewall spacer around the first gate;
forming a second sidewall spacer on the sidewall of the gate recess prior to forming the second gate.

8. The method of claim 7, wherein the first sidewall spacer and the second sidewall spacer comprise nitride.

9. The method of claim 1, wherein the channel, the sacrificial region, and the mechanical support region comprise continuous monocrystalline silicon.

10. The method of claim 1, further comprising forming a second gate dielectric on the channel region after removing the sacrificial region and before forming the second gate.

11. The method of claim 10, wherein the first gate dielectric has a dielectric constant different from that of the second gate dielectric.

12. The method of claim 1, wherein the first gate comprises a different material than the second gate.

13. A semiconductor device, comprising:
a channel region;
a first gate dielectric on a first side of the channel region;
a second gate dielectric on a second side of the channel region;
a first gate on the first gate dielectric; and
a second gate on the second gate dielectric;
wherein the second gate is narrower where it is on the second gate dielectric than where it is spaced from the second gate dielectric.

14. The semiconductor device of claim 13, further comprising:
a first sidewall spacer around the first gate; and
a second sidewall spacer around the second gate.

15. The semiconductor device of claim 14, wherein the first sidewall spacer has an inner edge that is substantially vertical and outer edge that slopes toward the first gate and the second sidewall spacer has an inner edge that slopes away from the second gate and an outer edge that is substantially vertical.

16. A semiconductor device, comprising:
a channel region;
a first gate dielectric on a first side of the channel region;
a second gate dielectric on a second side of the channel region;
a first gate on the first gate dielectric; and
a second gate on the second gate dielectric;
a first sidewall spacer around the first gate; and
a second sidewall spacer around the second gate.
wherein the first sidewall spacer has an inner edge that is substantially vertical and outer edge that slopes toward the first gate and the second sidewall spacer has an inner edge that slopes away from the second gate and an outer edge that is substantially vertical.

17. A method of making a semiconductor device, comprising:
forming a first gate with a first sidewall spacer separated from a first substrate by a first gate dielectric, the first substrate comprising a channel of semiconductor material adjacent to the gate dielectric, a sacrificial region adjacent to the channel, and a mechanical support region adjacent the sacrificial region;
etching into the first substrate using the first gate and the first sidewall spacer as a mask to form recesses in the first substrate;
forming source/drain regions in the recesses;
providing a second substrate adjacent the gate for use as a mechanical support for the semiconductor device;
substantially removing the mechanical support region of the first substrate;
removing the sacrificial region to provide a gate recess having a sidewall;
forming a second sidewall spacer on the sidewall; and
forming a second gate in the gate recess and adjacent to the channel.

18. The method of claim 17, wherein the channel comprises silicon.

19. The method of claim 17 wherein the sacrificial layer comprises silicon germanium.

20. The method of claim 17, wherein the first substrate comprises silicon.

21. The method of claim 17, wherein the forming the source/drain regions comprises epitaxially growing silicon.

22. The method of claim 17, wherein the forming the source/drain regions comprises forming layers of silicide in the recesses.

23. The method of claim 17, the first and second sidewall spacers comprise nitride.

24. The method of claim 17, wherein the channel, the sacrificial region, and the mechanical support region comprise continuous monocrystalline silicon.

25. The method of claim 17, further comprising forming a second gate dielectric on the channel region after removing the sacrificial region and before forming the second gate.

26. The method of claim 25, wherein the first gate dielectric has a dielectric constant different from that of the second gate dielectric.

27. The method of claim 17, wherein the first gate comprises a different material than the second gate.

28. The method of claim 27, wherein one of the first gate or second gate comprises n-type doped polysilicon and the other of the first gate or second gate comprises p-type doped polysilicon.
